(19) United States
(12) Patent Application Publication
(10) Pub. No.: US 2013/0228212 A1
(43) Pub. Date: Sep. 5, 2013

(54) COMPONENT FOR FASTENING WIRE IN SOLAR MODULE AND SOLAR MODULE USING THE SAME

(71) Applicant: AU OPTRONICS CORPORATION, Hsin-Chu (TW)

(72) Inventors: Tung-I YEN, Hsin-Chu (TW); Meng-Hung Chiang, Hsin-Chu (TW); Min-Chien Kuo, Hsin-Chu (TW); Yi-Ming Huang, Hsin-Chu (TW)

(73) Assignee: AU Optronics Corporation, Hsin-Chu (TW)

(21) Appl. No.: 13/684,696

(22) Filed: Nov. 26, 2012

(30) Foreign Application Priority Data
Mar. 5, 2012 (CN) 201210059044.2

(51) Int. Cl. F16L 3/10; H01L 31/02

(52) U.S. Cl. CPC F16L 3/10; H01L 31/02013
USPC 136/251; 248/65

(57) ABSTRACT

A component for fastening wires in a solar module is disclosed. The component includes a fastener and an adhesive layer. The fastener includes a substrate, two hooks disposed on the substrate, and two bases. Two cavities are formed between the hooks and the substrate for receiving the wires. Each hook has an opening, and the bases connect to the substrate and are disposed corresponding to the openings. A surface of each of the bases facing away from the cavity is inclined relative to the substrate, and a surface of each of the bases facing the cavity is substantially vertical to the surface. The adhesive layer is disposed on a surface of the substrate which is opposite to the hooks. A solar module using the component is also disclosed.

### RELATED APPLICATIONS

This application claims priority to China Application Serial Number 201210059044.2, filed Mar. 5, 2012, which is herein incorporated by to reference.

### BACKGROUND

1. Technical Field

The present invention relates to a solar module. More particularly, the present invention relates to a component for fastening a wire in a solar module.

2. Description of Related Art

In recent years, energy issues have been the focus of much attention. In order to solve the problems associated with using fuel sources to meet energy demands, a variety of alternative energy technologies have been developed. Because solar energy has many advantages, such as being non-polluting and unlimited, it is a popular choice to replace oil energy. Therefore, more and more solar panels are being disposed on homes, buildings, etc., particularly at locations where there is abundant sunshine.

In order to receive sunlight, solar modules are typically exposed to the environment, and this includes exposure to strong winds. Therefore, there is a need to firmly fasten the components of solar modules.

### SUMMARY

An aspect of the invention provides a component for fastening a wire in a solar module. The component includes a fastener and an adhesive layer. The fastener includes substrate, two hooks disposed on the substrate, and two bases disposed on the substrate. A cavity is formed between each of the hooks and the substrate for receiving the wire, and each of the hooks has an opening. The bases are disposed corresponding to the openings. A surface of each of the bases facing away from the cavity is inclined relative to the substrate to form a guiding incline, and a surface of each of the bases facing the cavity is substantially vertical to the substrate to form a stopping surface. The adhesive layer is disposed on a surface of the substrate opposite to the hooks.

Each of the hooks further comprises a flange disposed at an area where the hook is connected to the substrate. An opening height of each of the openings is smaller than a diameter of the wire. The opening height of each of the openings is smaller than the diameter of the wire by 0.2 mm. A distance between the hooks is not smaller than three times the diameter of the wire. Each of the hooks comprises a handle portion, and the corresponding opening is defined by the handle portion and the guiding incline of the corresponding base. A sectional profile of each of the handle portions is V-shaped. The two hooks include a first hook and a second hook, the first hook is fastened on the substrate, and the second hook is slidably assembled to the substrate. The substrate comprises a slide rail, the slide rail comprises a plurality of slots, and the second hook comprises two protrusions for insertion into the slots.

Another aspect of the invention provides a solar module, which includes a frame; a top board, at least one solar cell, and a back board stacked in order and fastened in the frame; a junction box disposed on the back board; a wire connected to the junction box; and the component. The wire includes a first cable and a second cable, and the first cable and the second cable are respectively connected to a positive electrode and a negative electrode of the solar cell through the junction box. The first cable and the second cable are received in the cavities respectively. The solar module further includes an inverter disposed on the back board and connected to the junction box through the first cable and the second cable.

Each of the hooks further includes a flange disposed at an area where the hook is connected to the substrate. An opening height of each of the openings is smaller than a diameter of the wire. The opening height of each of the openings is smaller than the diameter of the wire by 0.2 mm. A distance between the hooks is not smaller than three times the diameter of the wire. Each of the hooks includes a handle portion, and the corresponding opening is defined by the handle portion and the guiding incline of the corresponding base. A sectional profile of each of the handle portions is V-shaped. The two hooks include a first hook and a second hooks, the first hook is fastened on the substrate, and the second hook is slidably assembled to the substrate. The substrate includes a slide rail, the slide rail includes a plurality of slots, and the second hook comprises two protrusions for insertion into the slots.

The exposed wire for connecting the junction box to the inverter in the solar module can be firmly fastened by the component provided by the invention. Therefore electric arcing that may result when the first and second cables of the wire cross over each other can be prevented.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A is a side view of an embodiment of a solar module of the invention;

FIG. 1B is a bottom view of the embodiment of the solar cell of the invention;

FIG. 2 is an exploded perspective view of an embodiment of a component for fastening a wire in a solar module of the invention;

FIG. 3 is a cross-sectional view of another embodiment of a component for fastening a wire in a solar module of the invention;

FIG. 4 is an exploded perspective view of another embodiment of a component for fastening a wire in a solar module of the invention; and

FIG. 5A and FIG. 5B are perspective views showing different states of a second hook achieved by sliding the second hook relative to a substrate of the embodiment in FIG. 4.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

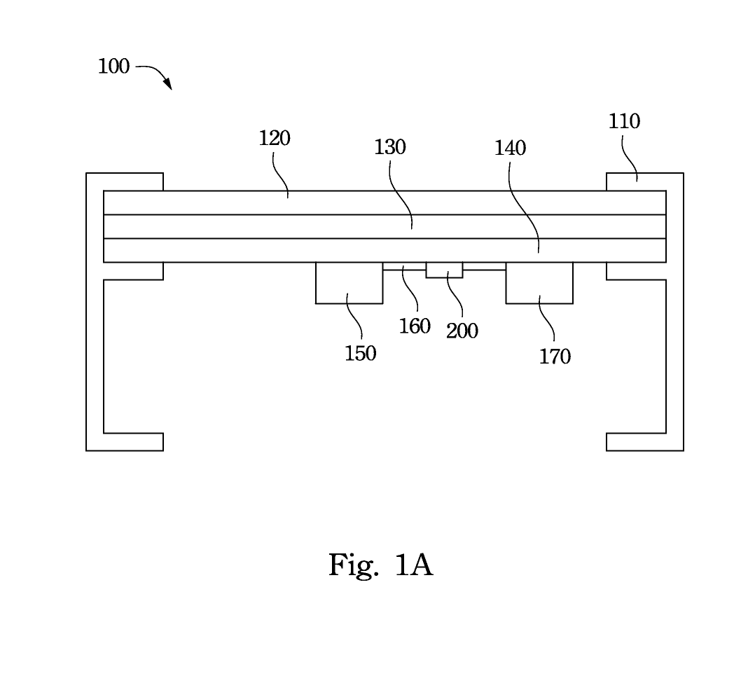

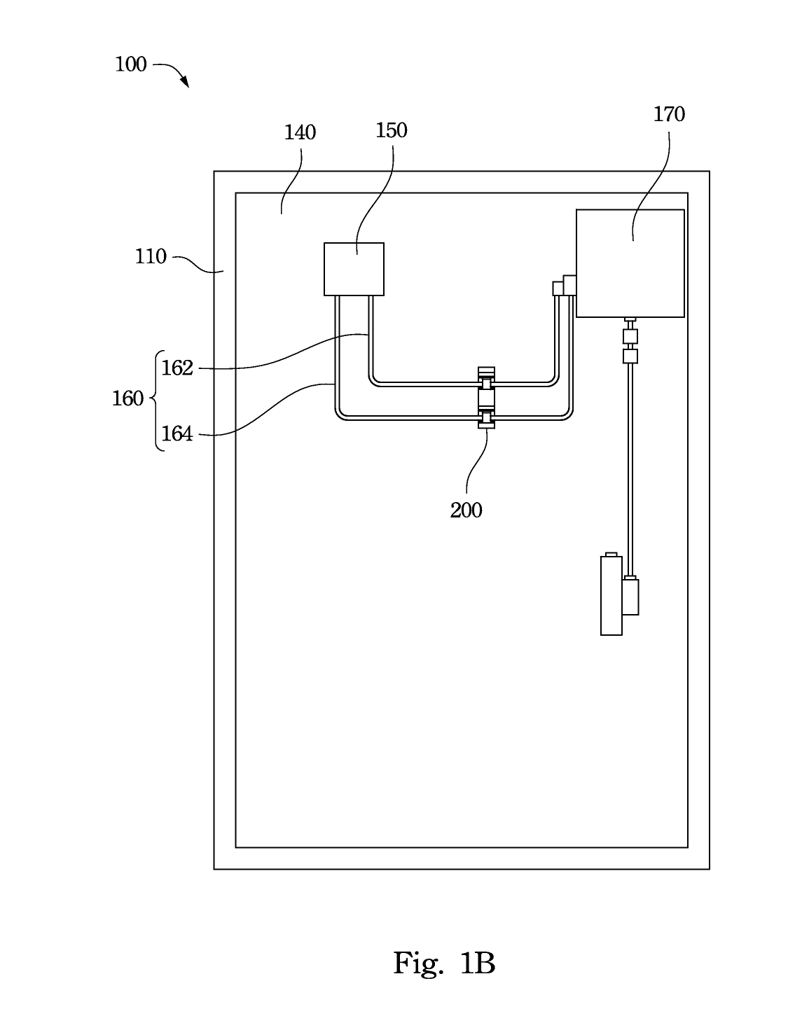

FIG. 1A is a side view of an embodiment of a solar module of the invention. FIG. 1B is a bottom view of the embodiment of the solar cell of the invention. The solar module 100 includes a frame 110, a top board 120, at least one solar cell 130, a back board 140, and a junction box 150. The top board 120, the solar cell 130, and the back board 140 are stacked in this order and fastened in the frame 110. The solar cell 130 is sandwiched between the top board 120 and the back board 140. The junction box 150 is disposed on the back board 140. The solar cell 100 further includes a wire 160 and an inverter 170. The wire 160 includes a first cable 162 and a second cable 164. The first cable 162 and the second cable 164 are respectively connected to the positive electrode and the negative electrode of the solar cell 130 through the junction box 150. The first cable 162 and the second cable 164 further connect the junction box 150 to the inverter 170. The inverter 170 is utilized to convert DC current to AC current.

Since the first cable 162 and the second cable 164 are respectively connected to the positive electrode and the negative electrode of the solar cell 130 via the junction box 150, the first cable 162 and the second cable 164 need to be fastened firmly to prevent electric arcing due to the first cable 162 and the second cable 164 crossing over each other. Electric arcing affects the stability of the solar module 100 and may result in damage to the wire 160 in some serious situations. Therefore the solar module 100 of the present invention further includes a component 200 for fastening the wire 160 in the solar module 100. The detailed structure and features of the component 200 are disclosed in the following embodiments.

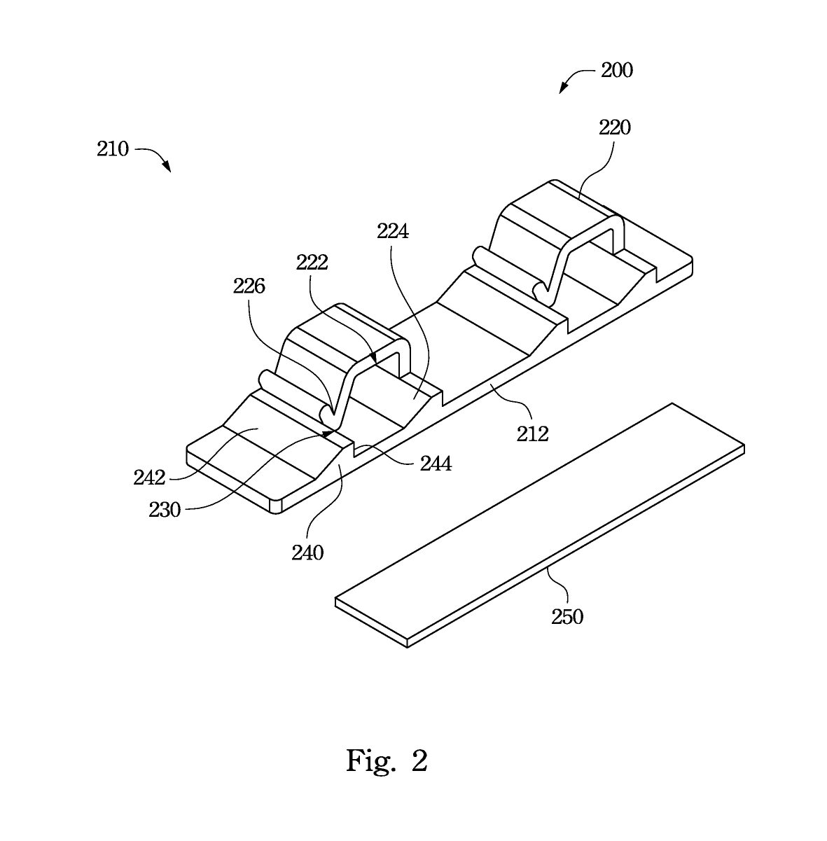

FIG. 2 is an exploded perspective view of an embodiment of the component 200 for fastening a wire in a solar module of the invention. The component 200 includes a fastener 210 and an adhesive layer 250. The fastener 210 includes a substrate 212, two hooks 220 disposed on the substrate 210, and two bases 240 disposed on the substrate 210. With additional reference to FIG. 1B, a cavity 222 is formed between each of the hooks 220 and the substrate 212 for receiving one of the two cables 162 or 164 of the wire 160. Each of the hooks 220 has an opening 230 for allowing one of the two cables 162 or 164 of the wire 160 to enter the cavity 222. More particularly, the first cable 162 and the second cable 164 may enter the cavities 222 via the openings 230 of the hooks 220 respectively, and the first cable 162 and the second cable 164 are fastened by the hooks 220.

The bases 240 are disposed on the substrate 212 corresponding respectively to the openings 230. Each of the bases 240 includes a guiding incline 242 and a stopping surface 244, in which the guiding incline 242 is arranged facing away from the corresponding cavity 222, and the stopping surface 244 is arranged facing the corresponding cavity 222. Each of the hooks 220 has a handle portion 226. Each of the openings 230 is defined between one of the handle portions 226 and the guiding incline 242 of the corresponding base 240. The sectional profile of each of the handle portions 226 is V-shaped, so that the corresponding opening 230 formed between the handle portion 226 and the corresponding guiding incline 242 may have a V-shaped profile, in which the V-shaped profile has a wide end and a narrow end. By such design, one of the two cables 162 or 164 of the wire 160 (see FIG. 1B) can easily enter the cavity 222 via the opening 230. As shown in FIG. 2, each of the stopping surfaces 244 is arranged vertically to the substrate 212 to prevent the wire from being removed from the cavity 222, and each of the guiding inclines 242 is arranged at an incline relative to the substrate 212.

Each of the hooks 220 further has a flange 224. The flange 224 is disposed at an area where the hook 220 is connected to the substrate 212. When one of the two cables 162 or 164 of the wire 160 (see FIG. 1B) enters the cavity 222, the flange 224 can be in contact with the one of the two cables 162 or 164 to increase the contact area between the one of the two cables 162 or 164 and the fastener 210, so that the one of the two cables 162 or 164 can be fastened in the cavity 222 firmly.

The adhesive layer 250 is disposed at the surface of the substrate 212 opposite to the hooks 220. The adhesive layer 250 is utilized to adhere the fastener 210 on the back board 140 of the solar module 100 (see FIGS. 1A and 1B). The fastener 210 can be formed as a single piece. The fastener 210 is made of a flexible nonconductive material, such as plastic.

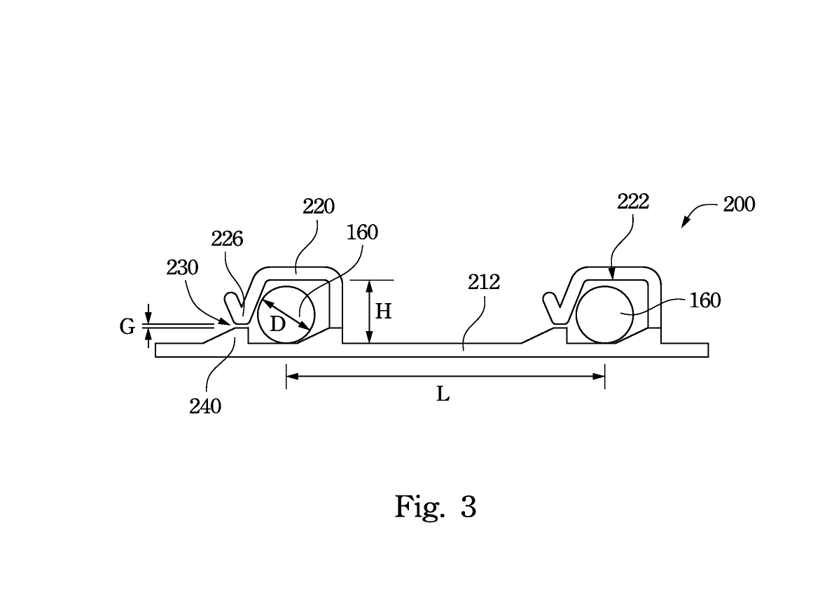

FIG. 3 is a cross-sectional view of another embodiment of a component for fastening a wire in a solar module of the invention. The dimensional relationships among the different elements of the component 200 are disclosed in this embodiment.

To simplify the description of this embodiment, the configuration corresponding to one of the hooks 220 and one of the bases 240 is described in the following, unless specifically stated otherwise (e.g., by stating “the two hooks 220”). Moreover, in the following description, “the wire 160” may be the first cable 162 or the second cable 164 shown in FIG. 1B, unless referred to as “the two wires 160,” in which case “the two wires 160” represent the first and second cables 162, 164.

The wire 160 has a diameter D. The cavity 222 has a height H, which is the distance from a top surface of the substrate 212 to the surface of the hook 220 facing the substrate 212. The opening 230 has an opening height G, which is the shortest distance between the handle portion 226 and the base 240. The distance between the two hooks 220 is represented by L, which can be a distance from a center of one of the cavities 222 to the center of the other cavity 222, or a distance from one of the bases 240 to the other base 240.

The height H of the cavity 222 is greater than the diameter D of the wire 160. The height H of the cavity 222 can be greater than the diameter D of the wire but smaller than twice the diameter D of the wire.

The opening height G of the opening 230 is smaller than the diameter D of the wire 160. The opening height G of the opening 230 can be smaller than the diameter D of the wire 160 by 0.2 mm for preventing the wire 160 from being removed from the opening 230.

The distance L between the two hooks 220 can be greater than three times the diameter D of the wire 160 to provide sufficient space for receiving two of the wires 160 respectively in the hooks 220, and enough space to allow the wires 160 to respectively enter the hooks 220.

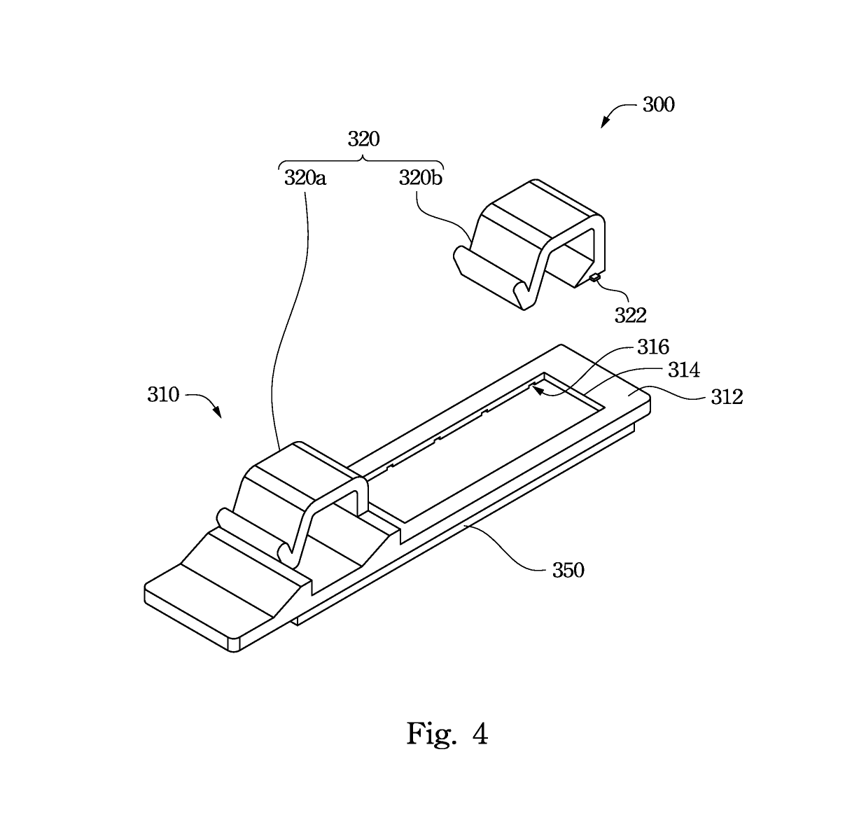

FIG. 4 is an exploded perspective view of another embodiment of a component for fastening a wire in a solar module of the invention. The component 300 includes a fastener 310 and an adhesive layer 350. The fastener 310 includes a substrate 312 and two hooks 320. The difference between this embodiment and the previous embodiments is that the hooks 320 in this embodiment include a first hook 320a and a second hook 320b, in which the first hook 320a is fastened on the substrate 312, and the second hook 320b is slidably assembled to the substrate 312.

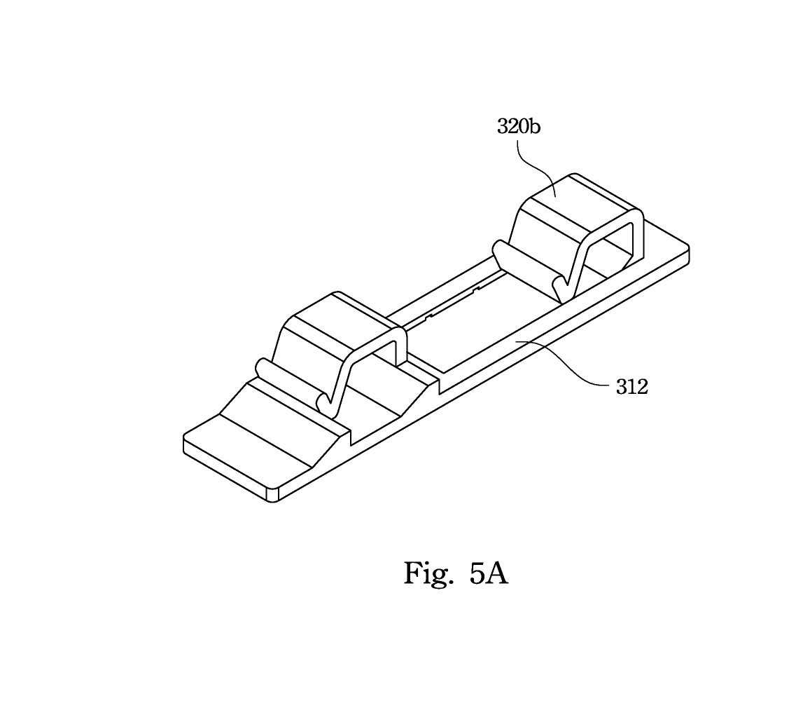

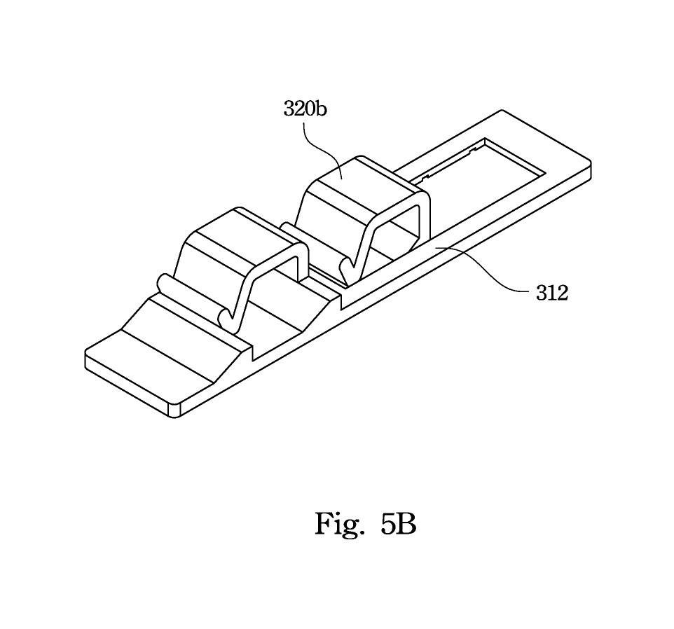

The substrate 312 includes a slide rail 314. The slide rail 314 includes a plurality of slots 316. The second hook 320b has two protrusions 322 for insertion into the slots 316. The second hook 320b is movably disposed on the substrate 312 and is positioned by coupling the protrusions 322 to the slots 316. The protrusions 322 are slid in the slide rail 314 and are coupled to two of the slots 316 to position the second hook 320b. The sliding of the second hook 320b can be performed before or after the wire (not shown) is inserted into the cavity. Different states of the second hook 320b which are achieved by sliding the second hook 320b relative to the substrate 312 of this embodiment are shown in FIG. 5A and FIG. 5B.

The exposed wire for connecting the junction box to the inverter in the solar module can be firmly fastened by the component provided by the invention. Therefore electric arcing that may result when the first and second cables of the wire cross over each other can be prevented.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their to equivalents.

What is claimed is:

1. A component for fastening a wire in a solar module comprising:
a fastener comprising:
a substrate;
two hooks disposed on the substrate, wherein a cavity is formed between each of the hooks and the substrate for receiving the wire, and each of the hooks has an opening; and
two bases disposed on the substrate corresponding to the openings, wherein a surface of each of the bases facing away from the cavity is inclined relative to the substrate to form a guiding incline, and a surface of each of the bases facing the cavity is substantially vertical to the substrate to form a stopping surface; and
an adhesive layer disposed on a surface of the substrate opposite to the hooks.

2. The component of claim 1, wherein each of the hooks further comprises a flange disposed at an area where the hook is connected to the substrate.

3. The component of claim 1, wherein an opening height of each of the openings is smaller than a diameter of the wire.

4. The component of claim 3, wherein the opening height of each of the openings is smaller than the diameter of the wire by 0.2 mm.

5. The component of claim 1, wherein a distance between the hooks is not smaller than three times the diameter of the wire.

6. The component of claim 1, wherein each of the hooks comprises a handle portion, and the corresponding opening is defined by the handle portion and the guiding incline of the corresponding base.

7. The component of claim 6, wherein a sectional profile of each of the handle portions is V-shaped.

8. The component of claim 1, wherein the two hooks comprise a first hook and a second hook, the first hook is fastened on the substrate, and the second hook is slidably assembled to the substrate.

9. The component of claim 8, wherein the substrate comprises a slide rail, the slide rail comprises a plurality of slots, and the second hook comprises two protrusions for insertion into the slots.

10. A solar module comprising:
a frame;
a top board, at least one solar cell, and a back board stacked in this order and fastened in the frame;
a junction box disposed on the back board;
a wire connected to the junction box, wherein the wire comprises a first cable and a second cable, and the first cable and the second cable are respectively connected to a positive electrode and a negative electrode of the solar cell through the junction box; and
the component of claim 1, wherein the first cable and the second cable are received in the cavities respectively.

11. The solar module of claim 10, further comprising an inverter disposed on the back board and connected to the junction box through the first cable and the second cable.

12. The solar module of claim 10, wherein each of the hooks further comprises a flange disposed at an area where the hook is connected to the substrate.

13. The solar module of claim 10, wherein an opening height of each of the openings is smaller than a diameter of the wire.

14. The solar module of claim 13, wherein the opening height of each of the openings is smaller than the diameter of the wire by 0.2 mm.

15. The solar module of claim 11, wherein a distance between the hooks is not smaller than three times the diameter of the wire.

16. The solar module of claim 11, wherein each of the hooks comprises a handle portion, and the corresponding opening is defined by the handle portion and the guiding incline of the corresponding base.

17. The solar module of claim 16, wherein a sectional profile of each of the handle portions is V-shaped.

18. The solar module of claim 10, wherein the two hooks comprise a first hook and a second hook, the first hook is fastened on the substrate, and the second hook is slidably assembled to the substrate.

19. The solar module of claim 18, wherein the substrate comprises a slide rail, the slide rail comprises a plurality of slots, and the second hook comprises two protrusions for insertion into the slots.
